(19) United States
(12) Patent Application Publication
(10) Pub. No.: US 2026/0018489 A1
(43) Pub. Date: Jan. 15, 2026

(54) SEMICONDUCTOR PACKAGE

(71) Applicant: Samsung Electronics Co., Ltd., Suwon-si (KR)

(72) Inventors: Deok Hee HAN, Suwon-si (KR); Yongjin SEOL, Suwon-si (KR)

(21) Appl. No.: 19/018,986

(22) Filed: Jan. 13, 2025

(30) Foreign Application Priority Data
Jul. 12, 2024 (KR) 10-2024-0092562

(51) Int. Cl. H01L 23/473; H01L 23/00; H01L 23/498; H01L 25/16; H10B 80/00; H10D 80/30

(52) U.S. Cl. CPC H01L 23/473; H01L 23/49833; H01L 23/49838; H01L 25/16; H01L 24/16; H01L 24/96; H01L 24/97; H01L 2224/16227; H01L 2224/16238; H01L 2224/96; H01L 2224/97; H01L 2924/1815; H10B 80/00; H10D 80/30

(57) ABSTRACT

The semiconductor package includes a lower package including a lower package substrate and a lower semiconductor device disposed on the lower package substrate, and an upper package including an upper package substrate disposed on the lower package in a first direction and an upper semiconductor device disposed on the upper package substrate, and the upper package substrate includes a wiring structure on which the upper semiconductor device is mounted, and a heat sink disposed so that at least a portion overlaps the wiring structure in at least one of the first direction and a second direction perpendicular to the first direction and including a heat radiation pattern, wherein the heat radiation pattern comprises an insulator and a heat radiator in a repeated alternating pattern and wherein the lower semiconductor device overlaps at least a portion of the wiring structure and the portion of the heat sink in the first direction.

### CROSS-REFERENCE TO RELATED APPLICATIONS

This application claims the benefit of Korean Patent Application No. 10-2024-0092562, filed on Jul. 12, 2024, in the Korean Intellectual Property Office, the disclosure of which is incorporated herein by reference.

### BACKGROUND OF THE INVENTION

### 1. Field of the Invention

The present disclosure relates to a semiconductor package.

### 2. Description of the Related Art

With development of electronic industry, integration density and an operation speed of a semiconductor chip (or device) are increasing as demands for high functionalization, high speed, and miniaturization of an electronic component are increasing. As the semiconductor chip is highly integrated and highly functionalized, heat generated in the semiconductor chip also increases in tandem. In order to satisfy recent demand for high-density integration and the high functionalization, performance and life of the semiconductor chip may be optimized by effectively discharging outward the heat generated in the semiconductor chip. When the heat generated in the semiconductor chip is not discharged, the performance of the semiconductor chip may be decreased due to the heat. In a worst case, the semiconductor chip may be damaged so as not to be normally functional.

### SUMMARY

An aspect provides a semiconductor package that may smoothly discharge heat generated in the semiconductor package.

Another aspect provides a semiconductor package that may improve durability while securing reliability of signal transmission between semiconductor devices.

However, the goals to be achieved by example embodiments of the present disclosure are not limited to the objectives described above and other objects may be clearly understood from the present disclosure and the accompanying drawings by those skilled in the art.

According to an aspect, there is provided a semiconductor package including a lower package comprising a lower package substrate and a lower semiconductor device disposed on the lower package substrate, and an upper package comprising an upper package substrate disposed on the lower package in a first direction and an upper semiconductor device disposed on the upper package substrate, and the upper package substrate includes a wiring structure on which the upper semiconductor device is mounted, and a heat sink disposed so that at least a portion overlaps the wiring structure in at least one of the first direction and a second direction perpendicular to the first direction and including a heat radiation pattern, wherein the heat radiation pattern comprises an insulator and a heat radiator arranged in a repeated alternating pattern in the first and second directions, wherein the heat sink is exposed to an exterior of the semiconductor package, and wherein the lower semiconductor device overlaps at least a portion of the wiring structure and the portion of the heat sink in the first direction.

According to another aspect, there is also provided a semiconductor package including a package substrate, and a semiconductor chip, and the package substrate includes a wiring structure in which a wiring line is formed and on which the semiconductor chip is mounted, and a heat sink to which a heat radiation pattern configured to emit heat is formed, and wherein the wiring structure and the heat sink are integrally formed.

According to still another aspect, there is also provided a semiconductor package including a lower package substrate, an upper package substrate disposed on the lower package substrate in a first direction and to which a wiring structure including a wiring line is formed and a heat sink having a multilayer structure heat radiation structure to which a plurality of heat radiation patterns is formed are integrally formed, a lower semiconductor device disposed on the lower package substrate and electrically connected to the lower package substrate, an upper semiconductor device disposed on the wiring structure and electrically connected with the wiring structure, a conductive structure disposed between the wiring structure and the lower package substrate and electrically connected to the wiring structure and the lower package substrate, a mold film surrounding the wiring structure and the lower semiconductor device, and an insulation film surrounding the wiring line and the heat radiation patterns, and the lower semiconductor device is disposed to overlap a portion of the heat sink and a portion of the wiring structure in the first direction, the mold film is spaced apart from an upper surface of the lower semiconductor device and the upper surface of the lower semiconductor device is in contact with the heat sink, a heat radiation pad comprising a metal material in a space between the lower semiconductor device and the heat sink, and an upper end and a lower end of the heat radiation pad are in contact with the heat sink and the lower semiconductor device, respectively.

Additional aspects of example embodiments will be set forth in part in the description which follows and, in part, will be apparent from the description, or may be learned by practice of the disclosure.

According to example embodiments, it is possible to improve heat radiation efficiency of a semiconductor package by shortening a heat radiation path of heat generated in the semiconductor package.

According to example embodiments, it is possible to improve durability of the semiconductor package while securing signal transmissibility.

According to example embodiments, it is possible to simplify a process of a package-on-package-type semiconductor package.

Effects of the present disclosure are not limited to those described above and other effects may be made apparent to those skilled in the art from the following description.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a layout diagram illustrating a semiconductor package according to an example embodiment;

FIG. 2 is a cross-sectional diagram illustrating an outline of a shape taken along line I-I of FIG. 1;

FIG. 3 is a cross-sectional diagram illustrating an outline of a path through which heat generated in a lower semiconductor device of FIG. 2 is emitted;

FIGS. 4 through 6 are diagrams illustrating an intermediate operation in order to describe a method of manufacturing a semiconductor package of FIG. 2 at a panel level;

FIG. 7 is a cross-sectional diagram illustrating an outline of a shape of a semiconductor package according to another example embodiment;

FIG. 8 is a cross-sectional diagram illustrating an outline of a shape of a semiconductor package according to still another example embodiment;

FIG. 9 is a cross-sectional diagram illustrating an outline of a shape of a semiconductor package according to still another example embodiment;

FIG. 10 is a cross-sectional diagram illustrating an outline of a shape of a semiconductor package according to still another example embodiment;

FIG. 11 is a cross-sectional diagram illustrating an outline of a shape of a semiconductor package according to still another example embodiment;

FIG. 12 is a cross-sectional diagram illustrating an outline of a shape of a semiconductor package according to still another example embodiment;

FIG. 13 is a cross-sectional diagram illustrating an outline of a shape of a semiconductor package according to still another example embodiment;

FIG. 14 is a cross-sectional diagram illustrating an outline of a shape of a upper package substrate according to still another example embodiment;

FIG. 15 is a diagram illustrating an outline of a shape of a heat radiation structure of FIG. 14 being manufactured at a panel level; and

FIG. 16 is a diagram illustrating an outline of a shape of a wiring structure of FIG. 14 being manufactured at a panel level.

### DETAILED DESCRIPTION

Example embodiments of the present disclosure that are described below may be modified and implemented in various forms. The technical spirit of the present disclosure is not limited to the embodiments described below. Terms used in the example embodiments are selected, as much as possible, from general terms that are widely used at present while taking into consideration functions obtained in accordance with the present disclosure, except terms that are arbitrarily selected and of which definitions are described in detail by the applicant in the present disclosure, but these terms may be replaced by other terms based on intentions of those skilled in the art, customs, emergence of new technologies, or the like. The terms used herein should be understood as including meanings and concepts corresponding to the technical spirit of the present disclosure, rather than being construed limitedly based on general definitions or dictionary definitions thereof.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

In the entire specification, when an element is referred to as “including” another element, the element should not be understood as excluding other elements so long as there is no special conflicting description, and the element may include at least one other element. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In the following descriptions, terms in a singular form include terms in a plural form unless an apparently and contextually conflicting description is present. Terms including an ordinal number such as “first” or “second” used in the present specification may be used to describe various elements. However, the elements may not be limited by the terms including the ordinal number. The terms may be used to contextually distinguish one element from another element in a part of the specification. Within a range of the technical spirit of the present disclosure, a first element may be referred to as a second element in another part of the specification, and reversely, the second element may be referred to as the first element in another part of the specification. Also, in the accompanying drawings, shapes, sizes, or the like of elements in the drawings may be exaggerated for clearer description. In addition, it should be noted in advance that an expression such as an upper side, a lower side, an upper portion, a lower portion, a side surface, an upper surface, or a lower surface is based on directions illustrated in the drawings and that the expression may be changed when a direction of a corresponding object is changed.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

The term “substrate” may denote a base substrate (e.g., an initial semiconductor substrate forming the base of the wafer in the final wafer product, such as a bulk semiconductor substrate (e.g., formed of crystalline silicon), an silicon on insulator (SOI) substrate, etc.), or a stack structure including such a base substrate and layers formed on the substrate.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited.

Hereinafter, the example embodiments of the present disclosure will be described with reference to the drawings so that those skilled in the art to which the present disclosure belong may easily carry out the present disclosure.

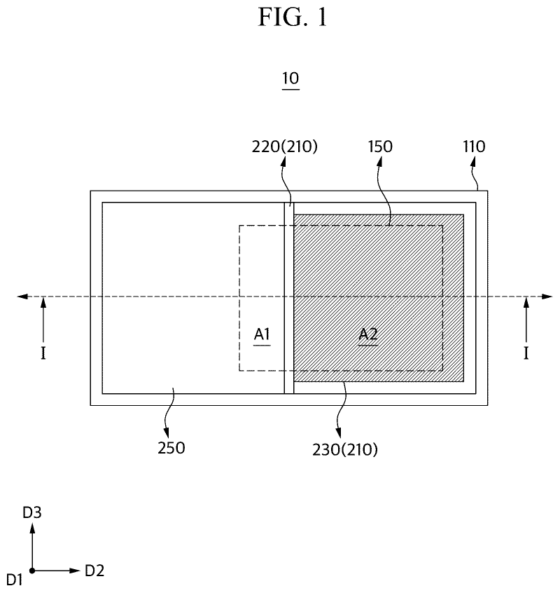

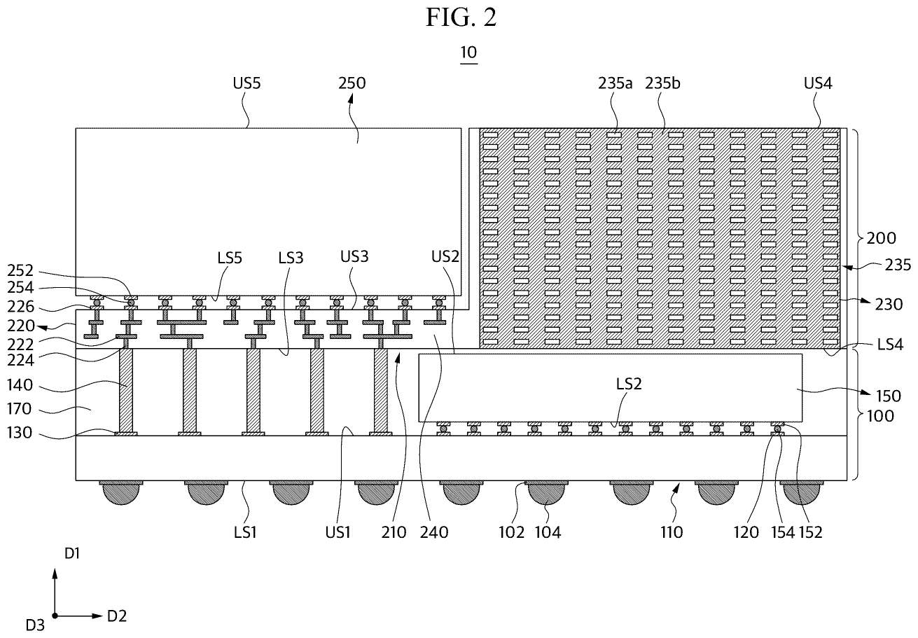

FIG. 1 is a layout diagram illustrating a semiconductor package according to an example embodiment. FIG. 2 is a cross-sectional diagram illustrating an outline of a shape taken along line I-I of FIG. 1. A dotted line illustrated in FIG. 1 shows a lower semiconductor device 150 disposed below an upper package substrate 210 that will be described below.

Referring to FIGS. 1 and 2, a semiconductor package 10 according some example embodiments may be a package-on-package-type semiconductor package in which a plurality of semiconductor packages is stacked to be electrically connected. However, it is merely an example. The semiconductor package 10 according to some example embodiments may be a system-in-package-type or package-in-package-type semiconductor package in which a plurality of semiconductor chips or a plurality of package substrates is electrically connected in one package and may also include various semiconductor packages in addition to the above-described packages. Hereinafter, in order to assist understanding, the semiconductor package 10 according to some example embodiments will be described as an example.

The semiconductor package 10 according to some example embodiments may include a lower package 100 and an upper package 200. The lower package 100 and the upper package 200 according to some example embodiments may be disposed in one direction. Hereinafter, the direction in which the lower package 100 and the upper package 200 are disposed will be defined as a first direction D1, and a direction perpendicular to the first direction D1 when the semiconductor package 10 is viewed from a side will be defined as a second direction D2. In addition, a direction perpendicular to a plane including all of the first direction D1 and the second direction D2 will be defined as a third direction D3. In some example embodiments, the first direction D1 may be a direction perpendicular to a ground surface. The first direction D1 may be referred to as a vertical direction, and the plane formed by the second and third directions D2 and D3 may be referred to as a horizontal plane.

The lower package 100 according to some example embodiments may include a lower package substrate 110, a conductive structure 140, and the lower semiconductor device 150. The lower package substrate 110 according to some example embodiments may be a wiring substrate for a package. For example, the lower package substrate 110 may be a printed circuit board (PCB), a ceramic wiring substrate, or the like. Also, the lower package substrate 110 may be a wiring substrate for a panel level package (PLP) manufactured at a panel level (e.g., for packaging performed on a large panel, rather than a wafer). However, it is merely an example. The lower package substrate 110 may be a wiring substrate for a wafer level package (WLP) manufactured at a wafer level (e.g., for packaging performed on the wafer before the wafer is diced or singulated). For example, if lower package substrate 110 is a printed circuit board, it may include at least one material selected from tetrafunctional epoxy, polyphenylene ether, epoxy/polyphenylene oxide, bismaleimide triazine (BT), Thermount, cyanate ester, and a liquid crystal polymer. Also, the lower package substrate 110 may include a resin (e.g., prepreg, Ajinomoto Build-up Film (ABF), FR-4, or bismaleimide triazine (BT)) impregnated together with an inorganic filler in a core material such as a glass fiber (e.g., a glass cloth or a glass fabric). However, the lower package substrate is not limited to the example described above and may also include various types of substrates.

In some example embodiments, although not illustrated, the lower package substrate 110 may include a lower insulation layer (not illustrated) and a lower wiring line (not illustrated). The lower insulation layer (not illustrated) according to some example embodiments may be disposed to surround the lower wiring line (not illustrated). The lower insulation layer (not illustrated) may be disposed in a single-layer structure or a multilayer structure. The lower insulation layer (not illustrated) may include an organic material such as a photoimageable dielectric (PID) material or a photosensitive polyimide (PSPI) material. For example, the photoimageable dielectric material may include at least one of photosensitive polyimide, polybenzoxazole, a phenolic polymer, and a benzocyclobutene-based polymer. In another example embodiment, the lower insulation layer (not illustrated) may be formed of an inorganic dielectric material such as silicon nitride and silicon oxide.

The lower wiring line (not illustrated) according to some example embodiments may include a conductive material. The lower wiring line (not illustrated) may include at least one of copper (Cu), tin (Sn), indium (In), lead (Pb), zinc (Zn), nickel (Ni), gold (Au), silver (Ag), antimony (Sb), bismuth (Bi), and a combination thereof, but it is merely an example. The lower wiring line (not illustrated) may be formed to have a vertical or horizontal length-wise direction in a single-layer structure or a multilayer structure in the lower package substrate 110.

An external connection pad 102 may be disposed on a lower surface LS1 of the lower package substrate 110 according to some example embodiments. According to some example embodiments, the external connection pad 102 may be disposed to be exposed from a lowest layer of the lower package substrate 110. A plurality of external connection pads 102 according to some example embodiments may be disposed on the lower surface LS1 of the lower package substrate 110, and each of the external connection pads 102 may be disposed to be spaced apart from another. The external connection pad 102 may include the conductive material. For example, the external connection pad 102 may include aluminum (Al), copper (Cu), or the like. In addition, the external connection pad 102 may be electrically connected with the lower wiring line (not illustrated) which is disposed in the lower package substrate 110. The external connection pad 102 may have a circular shape or a quadrangular shape, but a shape of the external connection pad 102 is not limited thereto.

An external connection terminal 104 configured to be connected with an external device may be disposed on the external connection pad 102 according to some example embodiments. The external connection terminal 104 according to some example embodiments may include the conductive material. The external connection terminal 104 may be attached to the external connection pad 102 to be electrically connected with the external connection pad 102 and accordingly may be electrically connected with the lower wiring line (not illustrated) disposed in the lower package substrate 110. The external connection terminal 104 may have a circular shape or a quadrangular shape (e.g., projected in a plane), but a shape of the external connection terminal 104 is not limited thereto.

A first lower connection pad 120 and a second lower connection pad 130 each may be disposed on an upper surface US1 of the lower package substrate 110 according to some example embodiments. Each of a plurality of first lower connection pads 120 and a plurality of second lower connection pads 130 may be disposed on the upper surface US1 of the lower package substrate 110. The plurality of first lower connection pads 120 may be disposed apart from each other by a predetermined distance, and the plurality of second lower connection pads 130 may be also disposed to be spaced apart from each other. The first lower connection pad 120 and the second lower connection pad 130 according to some example embodiments may be disposed in different areas on the upper surface US1 of the lower package substrate 110. According to some example embodiments, the first lower connection pad 120 and the second lower connection pad 130 may be individually disposed in areas facing each other when viewed from the upper surface US1 of the lower package substrate 110. For example, when the first lower connection pad 120 is viewed from the upper surface US1 of the lower package substrate 110, the first lower connection pad 120 may be disposed in an area to the right of a vertical line passing through a center of the lower package substrate 110. The second lower connection pad 130 may be disposed in an area to the left of the vertical line. However, it is merely an example.

According to some example embodiments, the first lower connection pad 120 and the second lower connection pad 130 may include the conductive material. For example, the first lower connection pad 120 and the second lower connection pad 130 may include at least one material selected from a group including copper (Cu), aluminum (Al), gold (Au), or the like. The first lower connection pad 120 and the second lower connection pad 130 may be electrically connected with the lower wiring line (not illustrated) of the lower package substrate 110. Accordingly, the first lower connection pad 120 and the second lower connection pad 130 each may be electrically connected with the external device through the lower wiring line (not illustrated), the external connection pad 102, and the external connection terminal 104. The first lower connection pad 120 and the second lower connection pad 130 according to some example embodiments may have a circular shape in general (e.g., projected in a plane), but shapes thereof are not limited thereto. For example, the first lower connection pad 120 and the second lower connection pad 130 may have various shapes such as an oval shape or a quadrangular shape depending on a design requirement.

The conductive structure 140 according to some example embodiments may be disposed on the upper surface US1 of the lower package substrate 110. For example, the conductive structure 140 may be disposed between the lower package substrate 110 and the upper package substrate 210 which will be described below. In some example embodiments, the conductive structure 140 may be formed in an area overlapping, in the first direction D1, a wiring structure 220 that will be described below (e.g., conductive structure 140 may be positioned below wiring structure 220 in the first direction D1, as illustrated in FIG. 2). Also, the conductive structure 140 may be disposed on the second lower connection pad 130. For example, a lower end of the conductive structure 140 may be in contact with an upper end of the second lower connection pad (e.g., second lower conductive pad) 130, and an upper end of the conductive structure 140 may be in contact with a lower end of the wiring structure 220 of the upper package substrate 210 which will be described below. Accordingly, the conductive structure 140 may electrically connect the second lower connection pad 130 and the wiring structure 220 to electrically connect the lower semiconductor device 150 and an upper semiconductor device 250 that will be described below. A detailed description thereof will be described below.

According to some example embodiments, the conductive structure 140 may be surrounded by a mold film 170 that will be described below. In addition, the conductive structure 140 may penetrate the mold film 170 to extend in the first direction D1. The conductive structure 140 may include the conductive material. For example, the conductive structure 140 may be formed of copper (Cu). The conductive structure 140 may be a conductive post. Also, the conductive structure 140 may be formed by forming a via in the mold film 170 and coupling a solder ball disposed in a lower portion of the wiring structure 220 and a solder ball disposed on the lower package substrate 110 in the mold film 170. Though a single conductive structure 140 is described above, as can be seen in FIG. 2, a plurality of conductive structures are 140 included. However, the conductive structures 140 according to some example embodiments are not limited to the above-described example shapes, sizes, or arrangements, and are to be understood as a concept including various vertical connection conductors for electrically connecting different wiring structures.

The lower semiconductor device 150 according to some example embodiments may be a semiconductor chip. According to some example embodiments, the lower semiconductor device 150 may be a logic chip. For example, the logic chip may include a microprocessor, an analog element, or a digital signal processor. For example, the logic chip may be the microprocessor, the analog element, or the digital signal processor, such as a central processing unit (CPU), a graphic processing unit (GPU), or an application processor (AP). However, the lower semiconductor device 150 is not limited to the above-described example and may include a system-on-chip (SOC) that integrates all required elements of a system, such as a memory chip, an image chip including a charge coupled device (CCD) image sensor or a complementary metal oxide semiconductor (CMOS) image sensor, a microprocessor, a memory, and/or an input/output interface, in one chip. Here, the memory chip may include a volatile memory chip such as a dynamic random access memory (DRAM) or a static random access memory (SRAM) or a non-volatile memory chip such as a phase-change random access memory (PRAM), a magnetoresistive random access memory (MRAM), a ferroelectric random access memory (FeRAM), or a resistive random access memory (RRAM).

In some example embodiments, the lower semiconductor device 150 may include a substrate and a wiring structure. The substrate of the lower semiconductor device 150 may include silicon (Si), for example, crystalline silicon, polycrystalline silicon, or amorphous silicon. Furthermore, the substrate of the lower semiconductor device 150 may include a semiconductor element such as germanium (Ge), or a compound semiconductor such as silicon carbide (SiC), gallium arsenide (GaAs), indium arsenide (InAs), and indium phosphide (InP). Meanwhile, the substrate of the lower semiconductor device 150 may have a silicon-on-insulator (SOI) structure. For example, the substrate of the lower semiconductor device 150 may include a buried oxide (BOX) layer. The substrate of the lower semiconductor device 150 may include a conductive area, for example, a well doped with an impurity or a structure doped with the impurity. In addition, the substrate of the lower semiconductor device 150 may have various element isolation structures such as a shallow trench isolation (STI) structure.

In some example embodiments, the wiring structure of the lower semiconductor device 150 may be formed on the substrate of the lower semiconductor device 150. The wiring structure of the lower semiconductor device 150 may include a wiring pattern forming multiple layers, a wiring via vertically connecting wiring patterns of a multilayer structure, and an insulation layer for insulating the wiring pattern of the multilayer structure and the wiring via. Such an insulation layer may have a single-layer structure or a multilayer structure. The wiring pattern and the wiring via may include the conductive material.

In some example embodiments, the lower semiconductor device 150 may include at least one circuit element. The circuit element of the lower semiconductor device 150 may be electrically connected with the lower package substrate 110 through a first connection pad 152, a first connection bump 154, and the first lower connection pad 120, which will be described below, and may send and receive an electrical signal to and from the external device. Also, the circuit element of the lower semiconductor device 150 may be electrically connected with the lower wiring line (not illustrated) disposed in the lower package substrate 110 to send and receive an electrical signal to and from the upper semiconductor device 250 which will be described below.

In some example embodiments, the first connection pad 152 may be disposed on the lower semiconductor device 150. A plurality of first connection pads 152 may be disposed on a lower surface LS2 of the lower semiconductor device 150. The plurality of first connection pads 152 may be disposed to be spaced apart from each other. For example, the first connection pads 152 may be disposed at positions matched, on a one-to-one basis, to the first lower connection pads 120 which are disposed on the lower package substrate 110. In addition, the plurality of first connection pads 152 may include the conductive material. For example, the first connection pad 152 may include at least one of copper (Cu), tin (Sn), indium (In), lead (Pb), zinc (Zn), nickel (Ni), gold (Au), silver (Ag), antimony (Sb), bismuth (Bi), and the combination thereof, but it is merely an example. Although not illustrated, a passivation layer (not illustrated) for protecting an internal structure of the lower semiconductor device 150 from an external environment or collision may be additionally formed on the lower surface LS2 of the lower semiconductor device 150. The passivation layer (not illustrated) formed on the lower surface LS2 of the lower semiconductor device 150 may include solder resist, but a material of the passivation layer (not illustrated) may vary depending on a type of the lower semiconductor device 150. In some example embodiments, the first connection pad 152 may be disposed to be exposed from an opening portion formed in the passivation layer. However, it is merely an example. The passivation layer may not be formed on the lower surface LS2 of the lower semiconductor device 150, and a lower surface of the first connection pad 152 and the lower surface LS2 of the lower semiconductor device 150 may be coplanar while the first connection pad 152 is disposed in the lower semiconductor device 150.

In some example embodiments, the first connection bump 154 may be disposed on the first connection pad 152. For example, the first connection bump 154 may be disposed between the first connection pad 152 and the first lower connection pad 120. The first connection bump 154 may include the conductive material. For example, the first connection bump 154 may include a material identical or similar to that of the first connection pad 152. In some example embodiments, the first connection bump 154 may be a micro bump, a solder bump, or a solder ball, but this is merely an example. For example, the first connection bump 154 may have various shapes of a ball, a pin, a pillar, or the like. Also, the numbers of the first connection pads 152 and first connection bumps 154, intervals between the first connection pads 152 and between the first connection bumps 154, a shape of disposition of the first connection pads 152 and the first connection bumps 154, or the like is not limited by this illustration and may also vary depending on the design.

In some example embodiments, the lower semiconductor device 150 may be mounted on the lower package substrate 110. For example, the lower semiconductor device 150 may be bonded in a flip-chip bonding manner and mounted on the lower package substrate 110 through the above-described first connection pad 152 and first connection bump 154. However, it is merely an example. The lower semiconductor device 150 may be bonded on the lower package substrate 110 in a wire bonding manner. The lower semiconductor device 150 may be disposed between the lower package substrate 110 and the upper package substrate 210. In some example embodiments, the lower semiconductor device 150 may be disposed at a side of an area in which the conductive structure 140 is disposed. For example, the lower semiconductor device 150 and the conductive structure 140 may be individually disposed in different areas on the upper surface US1 of the lower package substrate 110.

In some example embodiments, the lower semiconductor device 150 may overlap, in the first direction D1, at least a portion of a heat radiation structure 230 that will be described below (e.g., lower semiconductor device 150 may be positioned at least partially below heat radiation structure 230 in the first direction D1, as illustrated in FIG. 2). The heat radiation structure 230 may also be referred to as a heat sink. In addition, the lower semiconductor device 150 may overlap a portion of the wiring structure 220 and at least a portion of the upper semiconductor device 250 in the first direction D1. For example, the lower semiconductor device 150 may be disposed to overlap the heat radiation structure (e.g., heat sink) 230 and the wiring structure 220 in different areas in the first direction D1 (e.g., lower semiconductor device 150 may be positioned at least partially below heat radiation structure 230 and wiring structure 220). However, this is merely one example. In some example embodiments, in the first direction D1, the lower semiconductor device 150 may overlap at least a portion of the heat radiation structure 230, as mentioned above, but may not overlap the wiring structure 220. According to some example embodiments, the lower semiconductor device 150 may include a first area A1 and a second area A2 different from the first area A1. Here, the first area A1 may be an area of the lower semiconductor device 150 overlapping (e.g. positioned below) the wiring structure 220 and/or the upper semiconductor device 250 (which may be positioned above the wiring structure 220) in the first direction D1. Also, the second area A2 may be an area of lower semiconductor device 150 overlapping (e.g. positioned below) the heat radiation structure 230 in the first direction D1. In some example embodiments, a size of the second area A2 may be larger than a size of the first area A1.

The mold film 170 according to some example embodiments may surround the above-described conductive structure 140 and the lower semiconductor device 150. For example, the mold film 170 may surround a side surface of the conductive structure 140, and an upper surface of the mold film 170 and an upper surface of the conductive structure 140 may be generally coplanar. The upper surface of the mold film 170 may be in contact with lower surfaces LS3 and LS4 of the upper package 200, which will be described below. In addition, the mold film 170 may surround the second lower connection pad 130. The mold film 170 may surround the lower semiconductor device 150. For example, the mold film 170 may surround a side surface and an upper surface US2 of the lower semiconductor device 150. Accordingly, the upper surface US2 of the lower semiconductor device 150 may be positioned below the upper surface of the mold film 170, and the upper surface US2 of the lower semiconductor device 150 may be spaced apart, by a predetermined distance, from the lower surfaces LS3 and LS4 of the upper package 200 which will be described below. For example, the upper surface US2 of the lower semiconductor device 150 may be spaced apart, by the predetermined distance, from a lower surface LS 4 of the heat radiation structure 230 and a lower surface LS3 of the wiring structure 220, which will be described below. Also, in some example embodiments, the mold film 170 may surround each of the first lower connection pad 120, the first connection pad 152, and the first connection bump 154. However, this is merely an example. In another example embodiment, at least one of the first lower connection pad 120, the first connection pad 152, and the first connection bump 154 may be surrounded by an underfill film, and the underfill film may be surrounded by the mold film 170.

The mold film 170 according to some example embodiments may be a resin including epoxy, polyimide, or the like. For example, the resin may include a bisphenol-group epoxy resin, a polycyclic aromatic epoxy resin, an ortho-cresol novolac epoxy resin, a biphenyl-group epoxy resin, or a naphthalene-group epoxy resin.

The upper package 200 according to some example embodiments may be disposed on the lower package 100. For example, the upper package 200 and the lower package 100 may be disposed in the first direction D1. In addition, the upper package 200 and the lower package 100 may be disposed to face each other.

According to some example embodiments, the upper package substrate 210 may include the upper semiconductor device 250. The upper package substrate 210 according to some example embodiments may be a substrate for the panel level package (PLP) manufactured at the panel level. However, this is merely an example. The upper package substrate 210 may be a substrate for the wafer level package (WLP) manufactured at the wafer level.

The upper package substrate 210 according to some example embodiments may include the wiring structure 220 and the heat radiation structure 230. In some example embodiments, the wiring structure 220 and the heat radiation structure 230 may be integrally formed. In an example, the wiring structure 220 and the heat radiation structure 230 may be formed together in one process unit. For example, the wiring structure 220 and the heat radiation structure 230 may be formed together in a unit process at the panel level. The unit process may refer to a set of repeated steps for forming repeated layers of materials. A process unit may refer to a structure formed using a unit process. For example, the conductive layers, such as the wiring structure 220 and/or the heat radiator 235b (described below), may be formed using a single type of deposition process (e.g., sputtering, electroplating, or the like), and in some embodiments may have no grain boundaries therebetween. In another example, the insulator, such as insulator 235a (described below), may be formed at different levels of the same material, in some embodiments to have no grain boundaries therebetween.

In some example embodiments, the wiring structure 220 and the heat radiation structure 230 may be individually disposed in different areas of the upper package 200. According to some example embodiments, when projected in the first direction D1, the wiring structure 220 may be disposed in an area overlapping an area in which the second lower connection pad 130 or the conductive structure 140 is disposed. Also, as described above, the wiring structure 220 may be disposed to overlap (e.g., may be positioned above) the first area A1 of the lower semiconductor device 150 in the first direction D1. According to some example embodiments, the heat radiation structure 230 may be disposed at a side of the wiring structure 220. For example, when projected in the first direction D1, the heat radiation structure 230 may be disposed to overlap at least some areas of the lower semiconductor device 150. For example, as described above, the heat radiation structure 230 may be disposed at a position overlapping the second area A2 of the lower semiconductor device 150 in the first direction D1. In some example embodiments, projected in the first direction D1, a size of an area in which the heat radiation structure 230 and the lower semiconductor device 150 overlap each other (e.g., the area of an entire overlapping region between the heat radiation structure 230 and the lower semiconductor device 150) may be larger than a size of an area in which the wiring structure 220 and the lower semiconductor device 150 overlap each other (e.g., the area of an entire overlapping region between the wiring structure 220 and the lower semiconductor device 150).

The wiring structure 220 according to some example embodiments may include a wiring pattern 222 and a wiring via 224. The wiring pattern 222 and the wiring via 224 may be referred to as wiring lines 222 and 224. The wiring pattern 222 may extend in the second direction D2 and/or the third direction D3. The wiring via 224 may extend in the first direction D1. Wiring patterns 222 may be disposed in an identical (e.g., single) layer. In addition, the wiring patterns 222 may be spaced apart in the first direction D1 and disposed to form stacked layers. Wiring vias 224 may be spaced apart in the first direction D1 to vertically connect the wiring patterns 222 which are individually disposed in the stacked layers. For example, the wiring lines 222 and 224 may have a multilayer structure in which at least one wiring pattern 222 and at least one wiring via 224 are stacked alternately. In addition, the number, disposition, or arrangement of the wiring lines 222 and 224 is not limited to the example illustrated in FIG. 2. For example, wiring patterns 222 and wiring vias 224 which have larger or smaller numbers thereof, another disposition thereof, and/or another arrangement thereof may be included.

In some example embodiments, the wiring lines 222 and 224 may include a conductive material, such as the conductive materials discussed above. For example, the wiring line 222 and 224 may include or be at least one of copper (Cu), aluminum (Al), tin (Sn), indium (In), tungsten (W) lead (Pb), zinc (Zn), nickel (Ni), gold (Au), silver (Ag), antimony (Sb), bismuth (Bi), titanium (Ti), and a combination thereof, but this is merely an example.

In some example embodiments, the wiring lines 222 and 224 may be electrically connected with the lower package 100. For example, the wiring lines 222 and 224 may be electrically connected with the conductive structure 140. Accordingly, the wiring lines 222 and 224 may be electrically connected with the external device through the conductive structure 140. Also, the wiring lines 222 and 224 may be electrically connected with the wiring structure and/or the circuit element of the lower semiconductor device 150 of the lower package 100 through the conductive structure 140.

In some example embodiments, a wiring connection pad 226 may be disposed on the wiring structure 220. A plurality of wiring connection pads 226 may be disposed on an upper surface US3 of the wiring structure 220. The plurality of wiring connection pads 226 may be disposed to be spaced apart from each other. Although not illustrated, the wiring connection pad 226 may be exposed through an opening portion formed in a passivation layer (not illustrated) additionally placed on the upper surface US3 of the wiring structure 220. According to some example embodiments, the wiring connection pad 226 may include the conductive material. The wiring connection pad 226 may be electrically connected with the wiring lines 222 and 224.

The wiring pattern 222 and the wiring via 224 according to some example embodiments may be surrounded by an insulation film 240. In some example embodiments, the insulation film 240 which surrounds the wiring lines 222 and 224 is illustrated as a single layer, but the insulation film 240 may be formed in multiple layers to surround the wiring lines 222 and 224. In some example embodiments, the insulation film 240 may include or be an organic material, as discussed above, such as a photoimageable dielectric (PID) material or photosensitive polyimide (PSPI) material. For example, the photoimageable dielectric material may include at least one of the photosensitive polyimide, the polybenzoxazole, the phenolic polymer, and the benzocyclobutene-based polymer. In another example embodiment, the insulation film 240 may be formed of the inorganic dielectric material such as silicon nitride and silicon oxide.

The heat radiation structure 230 according to some example embodiments may include a heat radiation pattern 235. In some example embodiments, the heat radiation pattern 235 may have a grid shape, such as a repeated alternating pattern, in the cross-sectional plane of the first and second directions, D1 and D2, as shown in FIG. 2. For example, the grid shape may be formed by alternatingly disposing an insulator 235a and a heat radiator 235b, e.g. the heat radiation pattern 235 may include insulator 235a and a heat radiator 235b, as in the example of FIG. 2. Also, the heat radiation pattern 235 may be stacked in multiple layers. For example, in some example embodiments, the heat radiation structure 230 may have a structure formed by stacking a plurality of heat radiation patterns 235 in the multiple layers.

In one example, the heat radiation pattern 235 may possess 90 degree rotational symmetry about the D1 axis. For example, the insulator 235a may extend as parallel bars along the D3 direction in some layers, as shown in the cross-section of FIG. 2, and may also extend as parallel bars along the D2 direction in alternate layers in other cross-sections, e.g. offset from that of FIG. 2. Likewise, the heat radiator 235b may extend as parallel bars along the D2 direction in some layers as shown in the cross-section of FIG. 2, and may also extend as parallel bars along the D3 direction in alternate layers, as also visible in FIG. 2.

In a second example, the heat radiation pattern 235 may be uniform along the third direction D3. For example, both the insulator 235a and the heat radiator 235b may extend as parallel bars along the D3 direction in some layers, as shown in the cross-section of FIG. 2. In alternate layers, the heat radiator 235b may form uniform sheets in the plane formed by the second and third directions, D2 and D3. However, these are merely non-limiting examples, and other arrangements are also possible.

A portion of the above-described insulation film 240 may form the insulator 235a of the heat radiation pattern 235. For example, the insulator 235a may include a material identical to that of the insulation film 240 and be formed together therewith in an identical unit process. For example, both insulator 235a and insulation film 240 may be deposited in a single process. For example, when depositing a particular layer of the insulation film 240, both the insulation film 240 depicted in the wiring structure 220 and the insulator 235a of the heat radiation pattern 235 may be formed at the same time. The heat radiator 235b may include a material having excellent thermal conductivity. Accordingly, the heat radiator 235b may differ from the insulator 235a at least due to its significantly higher thermal conductivity. In some example embodiments, the heat radiator 235b may include a material having thermal conductivity higher than that of the mold film 170. For example, the heat radiator 235b may include copper (Cu), silver (Ag), gold (Au), aluminum (Al), or the like. In some example embodiments, the heat radiator 235b may include a material identical to that of the wiring lines 222 and 224. For example, all of the heat radiator 235b and the wiring lines 222 and 224 may be copper (Cu). However, this is merely an example. All of the heat radiator 235b and the wiring lines 222 and 224 may include a material having electrical conductivity and excellent thermal conductivity.

The heat radiation pattern 235 according to some example embodiments may provide a path through which heat is emitted. As described above, since the heat radiator 235b of the heat radiation pattern 235 may include the material having the excellent thermal conductivity, heat generated in the semiconductor package 10 may be emitted to an outside of the semiconductor package 10 through the heat radiation pattern 235. A detailed description thereof will be described below.

Also, in some example embodiments, a side surface of the heat radiation structure 230 may be surrounded by the insulation film 240. In contrast, a lower surface LS4 and an upper surface US4 of the heat radiation structure 230 each may not be surrounded by the insulation film 240. For example, the lower surface LS4 of the heat radiation structure 230 may contact the upper surface of the mold film 170 of the lower package 100 described above, and the upper surface US4 of the heat radiation structure 230 may be exposed to the outside of the semiconductor package 10. Furthermore, the heat radiator 235b may be disposed at each of the upper surface US4 and the lower surface LS4 of the heat radiation structure 230. For example, the upper surface US4 of the heat radiation structure 230 may be disposed so that the heat radiator 235b, of the insulator 235a and the heat radiator 235b which form the heat radiation pattern 235, is exposed outward. In addition, the lower surface LS4 of the heat radiation structure 230 may be disposed so that the heat radiator 235b, of the insulator 235a and the heat radiator 235b, is in contact with the upper surface of the mold film 170. Accordingly, the heat radiator 235b which is exposed at the upper surface US4 of the heat radiation structure 230 may emit the heat generated in the semiconductor package 10 to the outside of the semiconductor package 10, and the lower surface LS4 of the heat radiation structure 230 may contribute to sending, to an inside of the heat radiation pattern 235, heat generated in the lower semiconductor device 150 which is disposed in the mold film 170.

In some example embodiments, the insulation film 240 which surrounds the side surface of the heat radiation structure 230 may be formed, in an identical unit process, together with the insulation film 240 which surrounds the wiring lines 222 and 224. In some example embodiments, the upper surface US4 of the heat radiation structure 230 may be disposed on a plane different from that of the upper surface US3 of the wiring structure 220. For example, the upper surface US4 of the heat radiation structure 230 may be disposed to be higher than the upper surface US3 of the wiring structure 220. Also, in some example embodiments, the lower surface LS4 of the heat radiation structure 230 and the lower surface LS3 of the wiring structure 220 may be coplanar. For example, from the lower surface LS1 of the lower package substrate 110, a vertical distance to the lower surface LS4 of the heat radiation structure 230 and a vertical distance to the lower surface LS3 of the wiring structure 220 may be equal.

As described above, since the wiring lines 222 and 224 and the heat radiator 235b of the heat radiation structure 230 include identical or similar materials, since the insulation film 240 is formed to surround each of the side surface of the heat radiation structure 230 and the wiring lines 222 and 224 in an identical unit process, and since the insulator 235a disposed alternately with the heat radiator 235b is formed together when the insulation film 240 is formed, the heat radiation structure 230 and the wiring structure 220 may be formed together in a unit process.

The upper semiconductor device 250 according to some example embodiments may be a semiconductor chip. According to some example embodiments, the upper semiconductor device 250 may be a semiconductor chip of a type different from that of the lower semiconductor device 150. In addition, the upper semiconductor device 250 may be a semiconductor chip that generates less heat than lower semiconductor device 150 does. In some example embodiments, the upper semiconductor device 250 may include a memory chip, while the lower semiconductor device 150 may include a logic chip as described above. For example, the upper semiconductor device 250 may include a volatile memory chip such as dynamic random access memory (DRAM) or static random access memory (SRAM) or non-volatile memory chip such as phase-change random access memory (PRAM), magnetoresistive random access memory (MRAM), ferroelectric random access memory (FeRAM), or resistive random access memory (RRAM). However, these are merely examples. The lower semiconductor device 150 may also include a central processing unit, a graphic processing unit, a logic chip including a microprocessor or the like, an image chip, a system-on-chip, or the like.

In some example embodiments, the upper semiconductor device 250 may include a substrate and a wiring structure. Since the substrate of the upper semiconductor device 250 and the wiring structure of the upper semiconductor device 250 may be approximately identical or similar to the above-described substrate and the above-described wiring structure of the lower semiconductor device 150, redundant descriptions will be omitted.

In some example embodiments, the upper semiconductor device 250 may be mounted on the upper package substrate 210. For example, the upper semiconductor device 250 may be disposed on the wiring structure 220. Accordingly, the upper semiconductor device 250 may overlap the wiring structure 220 in the first direction D1. In addition, at least a portion of the upper semiconductor device 250 may overlap the lower semiconductor device 150 in the first direction D1. For example, the upper semiconductor device 250 may be disposed to overlap the first area A1 of the lower semiconductor device 150 in the first direction D1. Also, one side surface of the upper semiconductor device 250 may be disposed to be spaced apart from the side surface of the heat radiation structure 230. Furthermore, the one side surface of the upper semiconductor device 250 may be disposed to be spaced apart from the insulation film 240 which surrounds the side surface of the heat radiation structure 230. Also, an upper surface US5 of the upper semiconductor device 250 and the upper surface US4 of the heat radiation structure 230 may be coplanar. For example, in the semiconductor package 10, a height from the ground surface to the upper surface US5 of the upper semiconductor device 250 and a height from the ground surface to the upper surface US4 of the heat radiation structure 230 may be equal. Therefore, overall structural stability of the semiconductor package 10 may be increased.

In some example embodiments, the upper semiconductor device 250 may be mounted on the upper package substrate 210 through a second connection pad 252 and a second connection bump 254. For example, the upper semiconductor device 250 may be bonded on the upper package substrate 210 in a flip-chip bonding manner. However, this is merely an example. The upper semiconductor device 250 may be bonded on the upper package substrate 210 in a wire bonding manner.

In some example embodiments, the second connection pad 252 may be disposed on a lower surface LS5 of the upper semiconductor device 250. A plurality of second connection pads 252 may be disposed on the lower surface LS5 of the upper semiconductor device 250, and each of the second connection pads 252 may be disposed to be spaced apart from another by a predetermined distance. The second connection pad 252 may include the conductive material. As an example, the second connection pad 252 may include a material identical or similar to that of the first connection pad 152. In addition, similarly to the above-described first connection pad 152, the second connection pad 252 may be exposed through an opening portion formed in a passivation layer (not illustrated) or may be disposed so that a horizontal level of a lower surface thereof and a horizontal level of the lower surface LS5 of the upper semiconductor device 250 is coplanar while the second connection pad 252 is disposed in the upper semiconductor device 250.

In some example embodiments, the second connection bump 254 may be disposed on the second connection pad 252. The number of second connection bumps 254 may correspond to the number of the second connection pads 252. Also, the second connection bumps 254 may be in contact with the second connection pads 252 on a one-to-one basis. The second connection bump 254 may include the conductive material and include a material identical or similar to that of the first connection bump 154 described above. In some example embodiments, similar to first connection bump 154, the second connection bump 254 may be a micro bump, a solder bump, or a solder ball, but this is merely an example. For example, the second connection bump 254 may have various shapes such as a ball, a pin, or a pillar. Also, in some cases, the second connection bump 254 may have a shape identical or similar to that of the first connection bump 154. However, this is merely an example. In some examples, shapes of the second connection bump 254 and the first connection bump 154 may differ from each other.

In some example embodiments, the second connection pad 252 may be electrically connected with the wiring structure and/or a circuit element of the upper semiconductor device 250. In addition, the second connection bump 254 may be electrically connected with the second connection pad 252 and electrically connected with the above-described wiring connection pad 226. For example, the upper semiconductor device 250 may be electrically connected with each of the wiring structure 220, the lower package substrate 110, and the lower semiconductor device 150, and accordingly, the upper semiconductor device 250 and the lower semiconductor device 150 may send and receive an electrical signal.

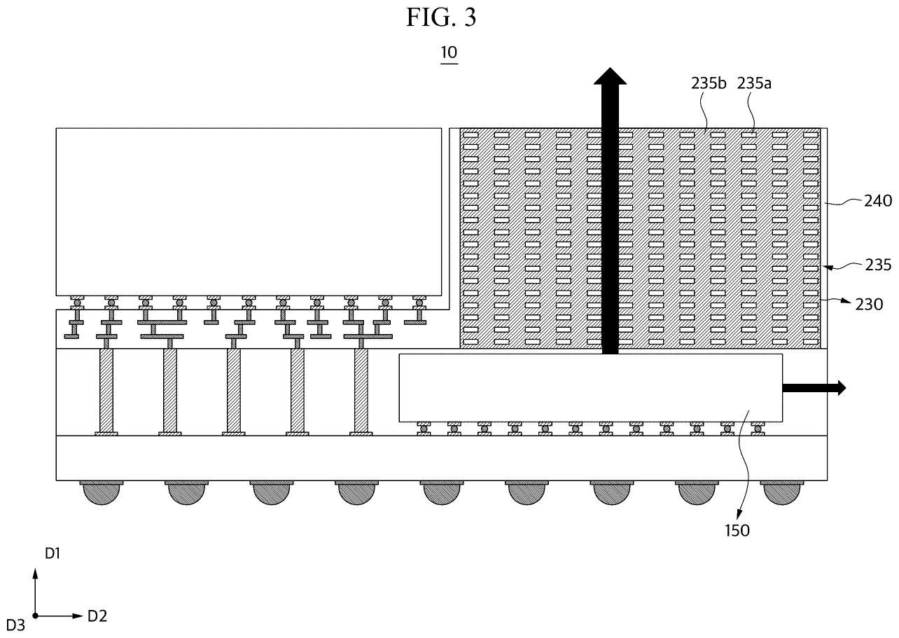

FIG. 3 is a cross-sectional diagram illustrating an outline of a path through which heat generated in a lower semiconductor device of FIG. 2 is emitted. An arrow illustrated in FIG. 3 may show an outline of a path through which heat generated in the lower semiconductor device 150 is emitted. It may be understood that as a size of the arrow in FIG. 3 is larger, an amount of the heat emitted per unit time is relatively large. In addition, since the semiconductor package 10 in FIG. 3 is identical to that in FIG. 2, reference numerals of elements other than the lower semiconductor device 150, the heat radiation structure 230, or the like is omitted to assist understanding. Hereinafter, a mechanism of emitting the heat from the semiconductor package 10 according to some example embodiments will be described.

Referring to FIGS. 1 through 3, the lower semiconductor device 150 generates the heat. For example, if the lower semiconductor device 150 includes a logic chip, a large amount of the heat may be generated due to high-speed operation, high-performance calculation, high-density integration, or the like. The heat generated in the lower semiconductor device 150 may be sent to the mold film 170 which surrounds at least a portion of the lower semiconductor device 150. The heat sent to the mold film 170 may be induced to be sent to the heat radiation structure 230. For example, since the heat radiator 235b of the heat radiation structure 230 may include a material having excellent thermal conductivity (e.g., copper (Cu)), the heat sent to the mold film 170 may flow more rapidly to the heat radiation structure 230, of which thermal conductivity is higher than that of the mold film 170. Accordingly, the heat generated in the lower semiconductor device 150 may be emitted to an outside of the semiconductor package 10 by sequentially passing through the mold film 170 and the heat radiation structure 230 which has the heat radiation pattern 235. As shown by the arrow pointing in the D2 direction, a portion of the heat sent from the lower semiconductor device 150 to the mold film 170 may be emitted to the outside of the semiconductor package 10 by passing through the mold film 170, but the amount of heat which is emitted through such a path may be relatively smaller than the amount of heat which is emitted by the heat radiation structure 230.

According to some example embodiments described above, since the heat which is generated in a process of operation of the lower semiconductor device 150 may be effectively emitted to the outside of the semiconductor package 10 through the heat radiation structure 230, durability of the semiconductor package 10, including the lower semiconductor device 150, may be improved. In addition, since the heat radiation pattern 235 is stacked and formed in multiple layers, the thermal conductivity of the heat radiation structure 230 according to some example embodiments may be further improved. Also, since the heat radiator 235b which forms the heat radiation pattern 235 is disposed at the upper surface US4 of the heat radiation structure 230 according to some example embodiments so as to be exposed to the outside of the semiconductor package 10, efficiency of emission of the heat to the outside may be improved. Furthermore, since the heat radiator 235b is disposed at the lower surface LS4 of the heat radiation structure 230 according to some example embodiments so as to be in contact with the mold film 170, the heat generated in the lower semiconductor device 150 may be induced to be sent to the heat radiator 235b through the mold film 170. Also, an additional adhesive layer may not be disposed between an upper surface of the lower package 100 (e.g., an upper surface of the mold film 170) and a lower surface of the upper package 200 (e.g., the lower surface of the heat radiation structure 230 and a lower surface of the wiring structure 220). Also, an additional thermal interface material (TIM) is not disposed on the lower surface of the heat radiation structure 230 and the upper surface of the mold film 170. Accordingly, the risk of structural damage to the semiconductor package due to damage to such an adhesive layer and/or the TIM by the heat generated by the lower semiconductor device 150 may be reduced, according to embodiments of the present disclosure. In addition, since the adhesive layer and/or the TIM is not required to be additionally formed, a manufacturing process of the disclosed semiconductor package 10 may be simplified, and a package manufacturing cost may be decreased.

Also, according to some example embodiments, at least a portion of the lower semiconductor device 150 may overlap the heat radiation structure 230 in the first direction D1, and at least another portion of the lower semiconductor device 150 may overlap the wiring structure 220 and/or the upper semiconductor device 250 in the first direction D1. For example, the lower semiconductor device 150 may be disposed to be asymmetrical to the wiring structure 220 and the heat radiation structure 230, e.g. it may overlap both in the first direction D1. Through such disposition, according to embodiments of the present disclosure, the heat generated in the lower semiconductor device 150 may be effectively emitted via the heat radiation structure 230, while a signal transmission path to the wiring structure 220 and/or the upper semiconductor device 250 may also be minimized. For example, durability of the disclosed semiconductor package 10 may be increased by improving heat radiation efficiency of the lower semiconductor device 150 while performance of the lower semiconductor device 150 is upheld (e.g., through efficient signal transmission).

In the above-described example, an example in which the heat radiation pattern 235 is stacked in the multiple layers has been described, but it is merely an example. In some other example embodiments, the heat radiation pattern 235 may have a single-layered structure, and the heat radiation pattern 235 and the wiring structure 220 may be integrally formed at a panel level.

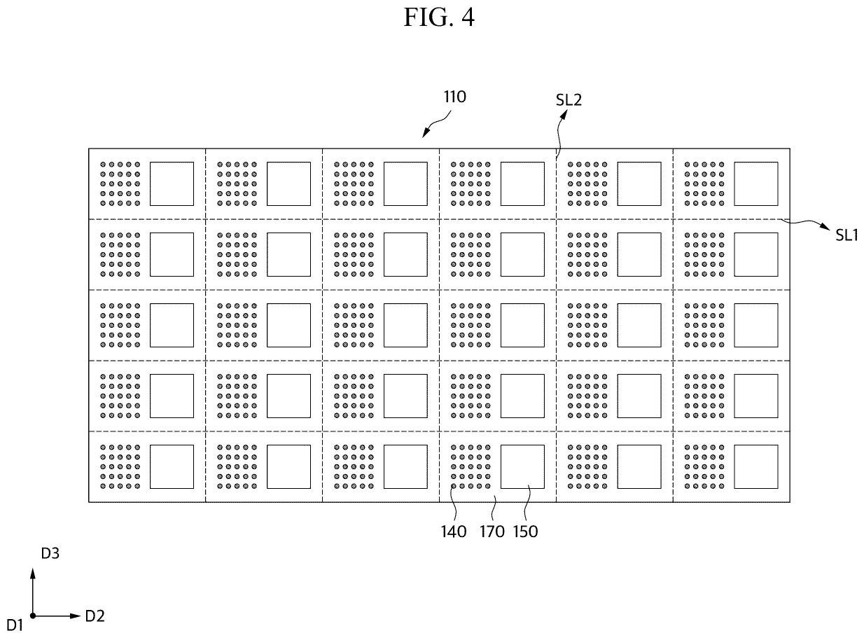

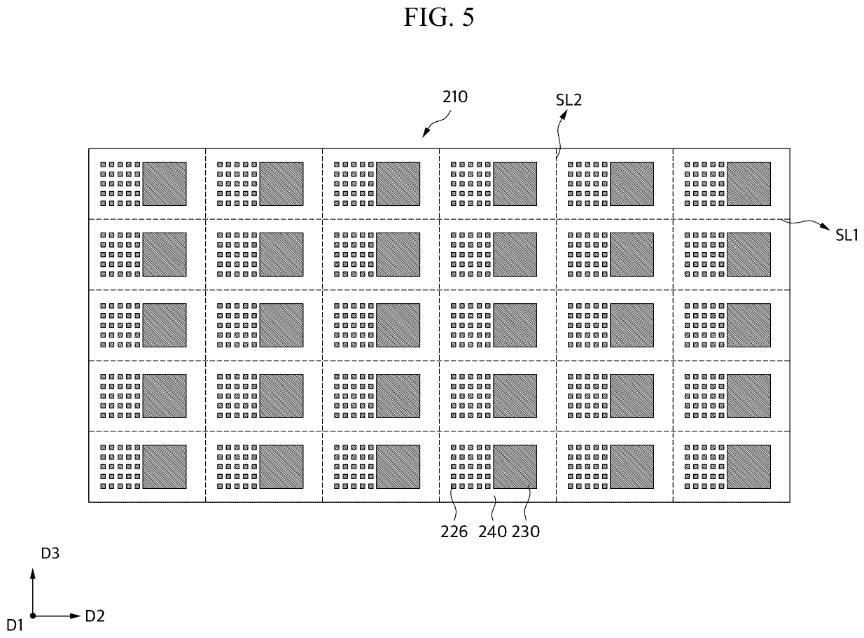

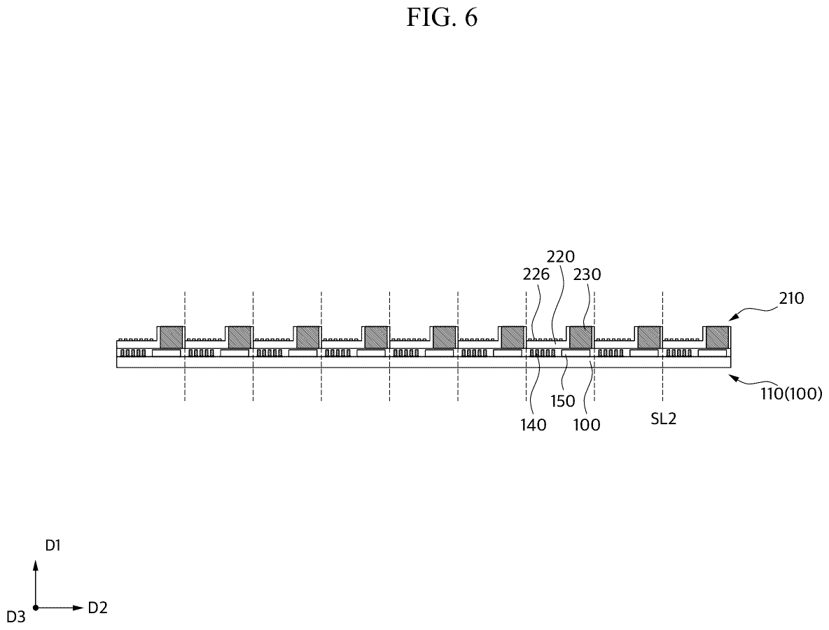

FIGS. 4 through 6 are diagrams illustrating an intermediate operation in order to describe a method of manufacturing a semiconductor package of FIG. 2 at a panel level. Specifically, FIG. 4 is a plan diagram illustrating an outline of the lower package 100 which is manufactured at the panel level. FIG. 5 is a plan diagram illustrating an outline of the upper package 200 which is manufactured at the panel level. FIG. 6 is a cross-sectional diagram illustrating an outline of a shape in which the lower package 100 of FIG. 4 and the upper package substrate 210 of FIG. 5 are stacked. Hereinafter, an example of an intermediate operation of manufacturing, at the panel level, the semiconductor package 10 which is described with reference to FIGS. 1 through 3 will be described.

Referring to FIGS. 1 through 6, the lower package substrate 110 according to some example embodiments may be a panel-level substrate. The lower package substrate 110 illustrated in FIG. 4 may be in a state in which a lower conductive structure 140 or the like is disposed thereon, the lower semiconductor device 150 is mounted thereon, and the mold film 170 fills a space thereon. The upper package substrate 210 according to some example embodiments may be a panel-level substrate. In some example embodiments, in the upper package substrate 210, the wiring structure 220 and the heat radiation structure 230 may be formed together at the panel level. In some example embodiments, the insulation film 240 which surrounds the wiring lines 222 and 224 and the insulation film 240 which surrounds a side surface of the heat radiation structure 230 may be formed together. The wiring lines 222 and 224 and the heat radiator 235b of the heat radiation structure 230 may be formed together. The insulator 235a of the heat radiation structure 230 may be also formed together when the insulation film 240 is formed.

In some example embodiments, the panel-level upper package substrate 210 may be stacked on the panel-level lower package substrate 110. A plurality of lower conductive structures 140, lower semiconductor devices 150, or the like may be disposed on the panel-level lower package substrate 110 as described above. In addition, the wiring connection pad 226 may be disposed on the panel-level upper package substrate 210 which includes a plurality of wiring structures 220 and a plurality of heat radiation structures 230. After the lower package substrate 110 and the upper package substrate 210 are stacked, the lower package substrate 110 and the upper package substrate 210 may be cut along sawing lines SL1 and SL2 in a subsequent process. For example, the lower package substrate 110 and the upper package substrate 210 may be cut along a first sawing line SL1 and a second sawing line SL2. Here, the first sawing line SL1 may be parallel to the second direction D2, and the second sawing line SL2 may be parallel to the third direction D3. At least one lower semiconductor device 150, at least one wiring structure 220, and at least one heat radiation structure 230 may be disposed to one semiconductor package 10 formed by cutting each of package substrates 110 and 210. According to some example embodiments, when the package substrates 110 and 210 are stacked to be cut, the upper semiconductor device 250 may not be mounted on the upper package substrate 210. For example, the upper semiconductor device 250 may be mounted on the wiring structure 220 after the upper package substrate 210 is stacked on the lower package substrate 110. However, this is merely an example. In a state in which the upper semiconductor device 250 is mounted on the wiring structure 220, the upper package substrate 210 may be stacked on the lower package substrate 110 and cut.

Hereinafter, a semiconductor package according to another example embodiment will be described. Hereinafter, since a structure and a function thereof are identical or similar to those of the above-described semiconductor package 10 unless additionally described, redundant descriptions will be omitted.

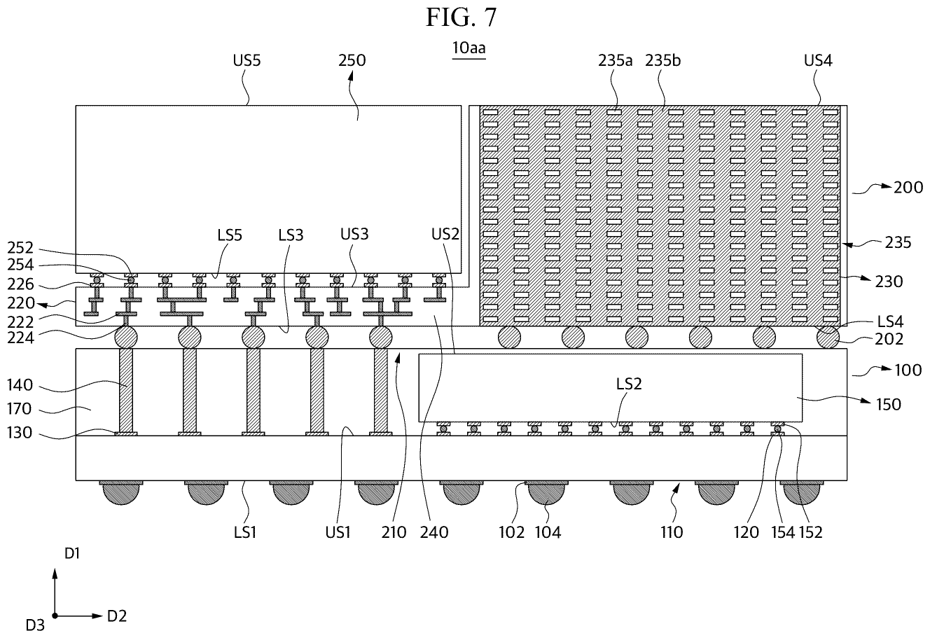

FIGS. 7 through 13 are cross-sectional diagrams illustrating an outline of a shape of a semiconductor package according to the respective example embodiments, which may be different from one another.

Referring to FIG. 7, a semiconductor package 10aa according to some example embodiments may further include a package connector 202. In some example embodiments, the package connector 202 may include a conductive material. The package connector 202 may be disposed between the lower package 100 and the upper package 200. For example, the package connector 202 may be formed on the lower surfaces LS3 and LS4 of the upper package 200. For example, the package connector 202 may be formed on the each of the lower surface LS3 of the wiring structure 220 and the lower surface LS4 of the heat radiation structure 230. Accordingly, after the lower package 100 and the upper package 200 each are manufactured at a panel level in some example embodiments as described above, the lower package 100 and the upper package 200 may be bonded by the package connector 202 formed on the lower surfaces LS3 and LS4 of the upper package 200. At this point, package connectors 202 formed on the lower surface LS3 of the wiring structure 220 may be individually disposed at positions matched to conductive structures 140 of the lower package 100 on a one-to-one basis in the first direction D1. In addition, the package connectors 202 formed on the lower surface LS3 of the wiring structure 220 may be electrically connected with the wiring lines 222 and 224 of the wiring structure 220. According to some example embodiments, the package connectors 202 may include solder balls having an oval, ellipsoidal, or spherical shape, but this is merely an example.

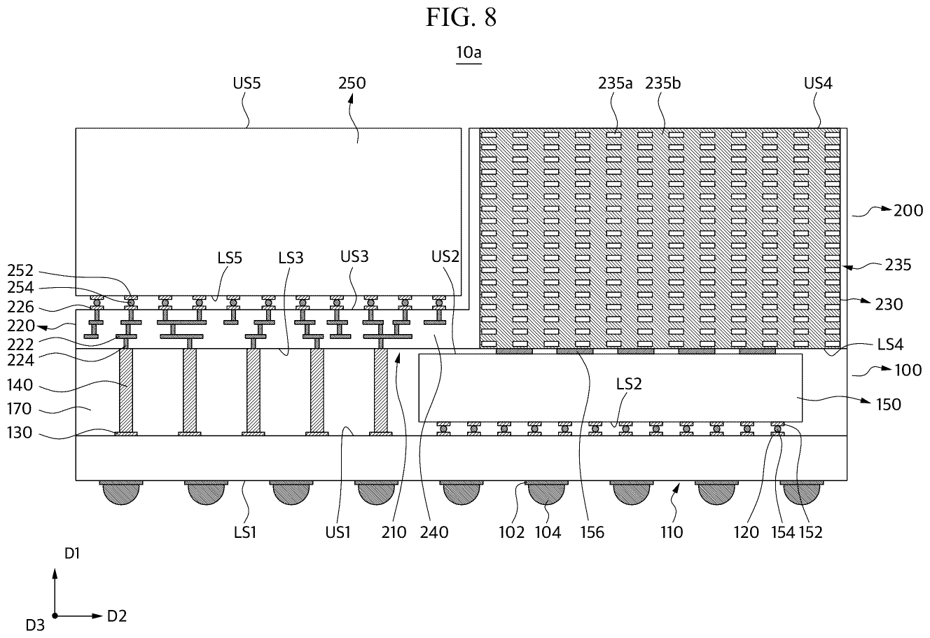

Referring to FIG. 8, a semiconductor package 10a according to some example embodiments may further include a heat radiation pad 156. The heat radiation pad 156 according to some example embodiments may be disposed on the lower semiconductor device 150. For example, the heat radiation pad 156 may be disposed in a space between the lower semiconductor device 150 and the heat radiation structure 230. Also, the heat radiation pad 156 may be disposed to be in contact with each of the upper surface US2 of the lower semiconductor device 150 and the lower surface LS4 of the heat radiation structure 230. Accordingly, the heat radiation pad 156 may be in contact with the heat radiator 235b which forms the heat radiation pattern 235 of the heat radiation structure 230. According to some example embodiments, a plurality of heat radiation pads 156 may be disposed in the space between the lower semiconductor device 150 and the heat radiation structure 230, and the plurality of heat radiation pads 156 may be disposed to be spaced apart from each other. The heat radiation pad 156 may generally have a circular shape or a quadrangular shape (e.g., projected in the plane of the second and third directions D2 and D3), but this is merely an example. In addition, the heat radiation pad 156 may include a material having excellent thermal conductivity. According to some example embodiments, the heat radiation pad 156 may include a material having thermal conductivity higher than that of the mold film 170. In some example embodiments, the heat radiation pad 156 may include a material identical or similar to that of a heat radiator 135b. In another example embodiments, the heat radiation pad 156 may include a material having thermal conductivity higher than that of the mold film 170 and lower than that of the heat radiator 135b. For example, the heat radiator 135b may include or be copper (Cu), and the heat radiation pad 156 may include or be aluminum (Al). In such a case, heat generated in the lower semiconductor device 150 may be induced to flow sequentially through the heat radiation pad 156 and the heat radiator 135b.

According to the above-described example embodiment, the heat radiation pad 156 may be placed in the space between the lower semiconductor device 150 and the heat radiation structure 230 to contact the lower semiconductor device 150 and the heat radiation structure 230. Accordingly, since the heat generated from the lower semiconductor device 150 may be directly sent to the heat radiation pad 156 having the excellent thermal conductivity, and since the heat sent to the heat radiation pad 156 may be sent again to the heat radiation structure 230 to be emitted to an outside of the semiconductor package 10, the high thermal conductivity of heat radiation pad 156 and heat radiator 135b may provide a most expeditious heat flow path away from lower semiconductor device 150. This example structure can thereby direct heat flow ultimately out of semiconductor package 10a, further increasing efficiency of emission of the heat.

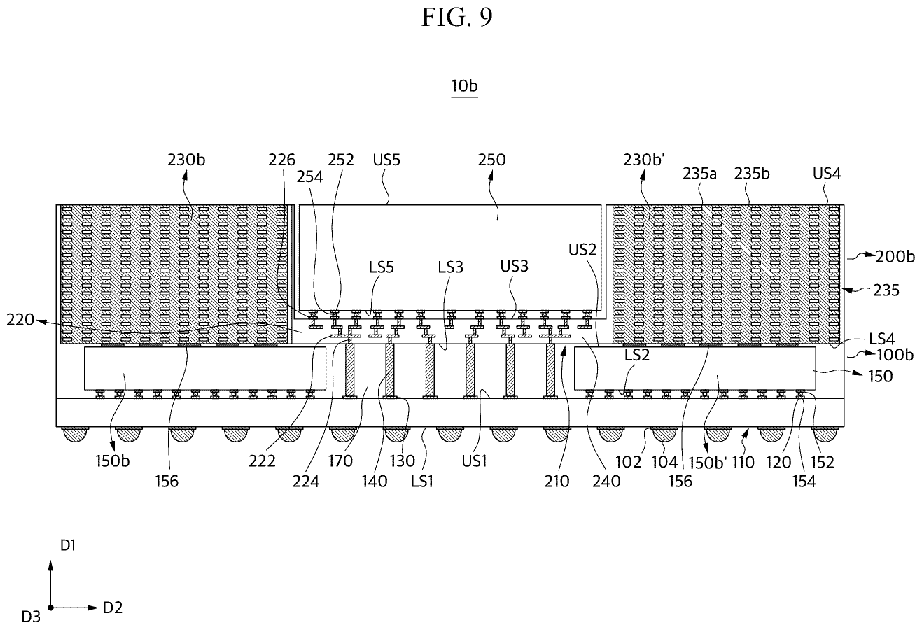

Referring to FIG. 9, a semiconductor package 10b according to some example embodiments may include a lower package 100b and an upper package 200b. The lower package 100b according to some example embodiments may include a first lower semiconductor device 150b and a second lower semiconductor device 150b′. The first lower semiconductor device 150b may be disposed at one side of the conductive structure 140. In addition, the second lower semiconductor device 150b′ may be disposed at another side of the conductive structure 140. For example, the first lower semiconductor device 150b and the second lower semiconductor device 150b′ may be individually formed at positions symmetrical to each other around the conductive structure 140 when viewed in the first direction D1.

The upper package 200b according to some example embodiments may include a first heat radiation structure 230b and a second heat radiation structure 230b′. The first heat radiation structure 230b, the second heat radiation structure 230b′, and the wiring structure 220 may be integrally formed. The first heat radiation structure 230b may be disposed at one side of the wiring structure 220. In addition, the second heat radiation structure 230b′ may be disposed at another side of the wiring structure 220. For example, the first heat radiation structure 230b and the second heat radiation structure 230b′ may be disposed to be symmetrical to each other around the wiring structure 220 when viewed in the first direction D1 (e.g., to be disposed at locations symmetrically arranged at opposite sides of the wiring structure 220). Also, the first heat radiation structure 230b and the second heat radiation structure 230b′ may be disposed to be symmetrical to each other around the upper semiconductor device 250 which is mounted on the wiring structure 220 when viewed in the first direction D1. Side surfaces of the first heat radiation structure 230b and the second heat radiation structure 230b′ may be disposed to be spaced apart from side surfaces of the upper semiconductor device 250 by a predetermined distance. In some example embodiments, the first lower semiconductor device 150b may overlap at least a portion of the first heat radiation structure 230b and at least a portion of the upper semiconductor device 250 and/or the wiring structure 220 in the first direction D1. Furthermore, the second lower semiconductor device 150b′ may overlap at least a portion of the second heat radiation structure 230b′ and at least a portion of the upper semiconductor device 250 and/or the wiring structure 220 in the first direction D1. In addition, a lower surface of the first heat radiation structure 230b, a lower surface of the second heat radiation structure 230b′, and a lower surface of the wiring structure 220 each may be coplanar. Also, an upper surface of the first heat radiation structure 230b, an upper surface of the second heat radiation structure 230b′, and an upper surface of the upper semiconductor device 250 each may be coplanar. In addition, the heat radiation pad 156 may be disposed in spaces between each of lower semiconductor devices 150b and 150b′ and a lower surface of each of heat radiation structures 230b and 230b′. However, this is merely an example. The heat radiation pad 156 may not be disposed in the spaces.

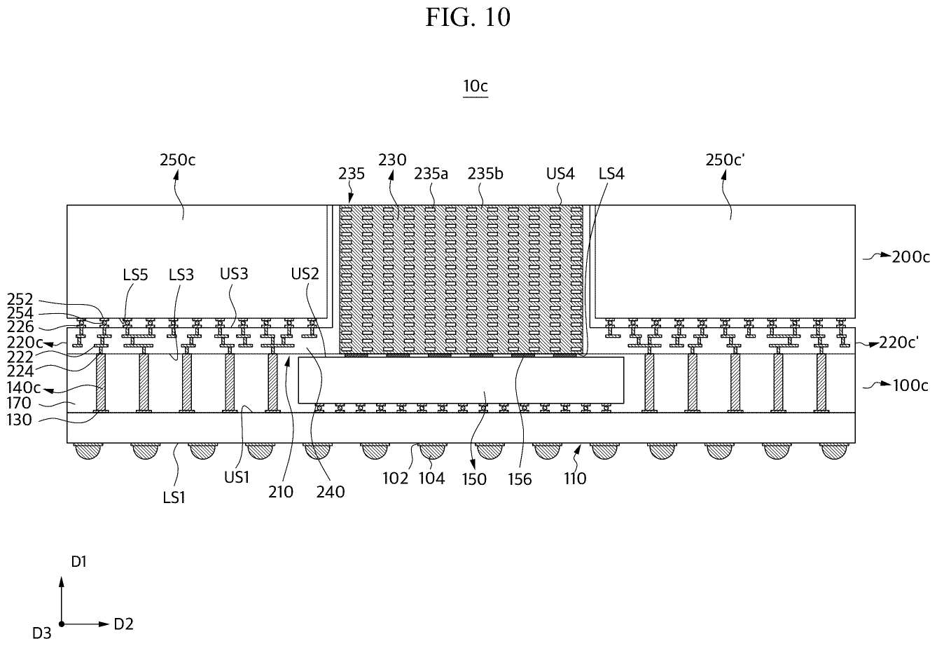

Referring to FIG. 10, a semiconductor package 10c according to some example embodiments may include a lower package 100c and an upper package 200c. A conductive structure 140c may be disposed on the lower package substrate 110. The conductive structure 140c may be disposed at a side of the lower semiconductor device 150 which is disposed on the lower package substrate 110. For example, a plurality of conductive structures 140c may be disposed, around the lower semiconductor device 150, at each facing side of the lower semiconductor device 150. In addition, the conductive structures 140c which are disposed at one side of the lower semiconductor device 150 may be electrically connected with a first wiring structure 220c that will be described below and may overlap, in the first direction D1, the first wiring structure 220c and/or a first upper semiconductor device 250c that will be described below. In addition, the conductive structures 140c which are disposed at another side opposite to the one side of the lower semiconductor device 150 may be electrically connected with a second wiring structure 220c′ that will be described below and may overlap, in the first direction D1, the second wiring structure 220c′ and/or a second upper semiconductor device 250c′ that will be described below.

The upper package 200c according to some example embodiments may include the first wiring structure 220c, the second wiring structure 220c′, the first upper semiconductor device 250c, and the second upper semiconductor device 250c′. In some example embodiments, the first wiring structure 220c and the second wiring structure 220c′ may be disposed to be opposite to each other with the heat radiation structure 230 in between. Also, in the first direction D1, at least a portion of the first wiring structure 220c and at least a portion of the second wiring structure 220c′ each may overlap the lower semiconductor device 150. An area in which the first wiring structure 220c overlaps the lower semiconductor device 150 may be an area different from an area in which the second wiring structure 220c′ overlaps the lower semiconductor device 150.

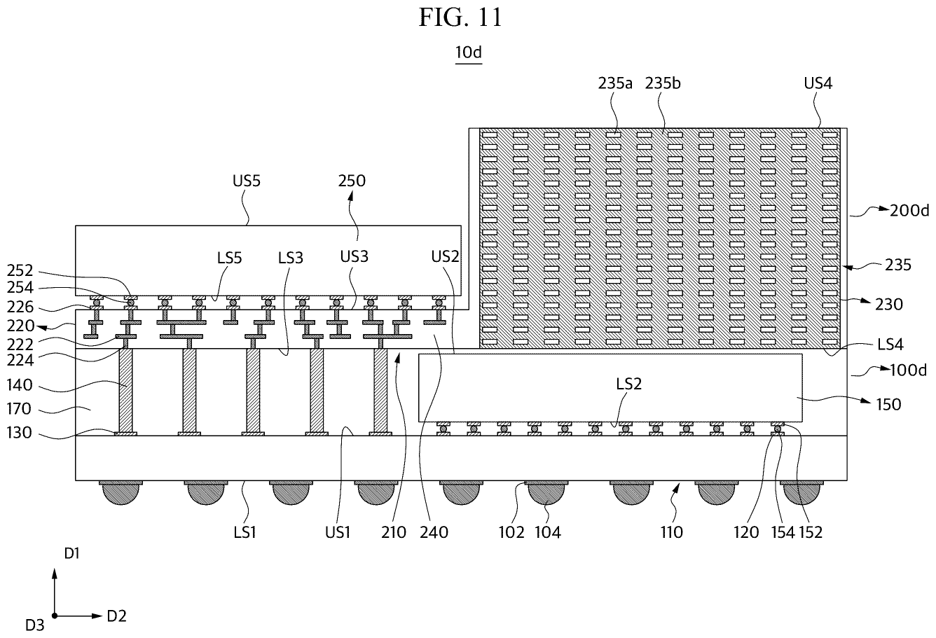

Referring to FIG. 11, in a semiconductor package 10d according to some example embodiments, the upper surface US4 of the heat radiation structure 230 and an upper surface US5 of an upper semiconductor device 250d may be positioned on different planes. For example, the upper surface US4 of the heat radiation structure 230 may be disposed to be higher than the upper surface US5 of the upper semiconductor device 250d. For example, a vertical distance from the upper surface US1 of the lower package substrate 110 to the upper surface US4 of the heat radiation structure 230 may be larger than a vertical distance from the upper surface US1 of the lower package substrate 110 to the upper surface US5 of the upper semiconductor device 250d. In some examples, the additional height of the heat radiation structure 230 may provide additional heat dissipation capacity.

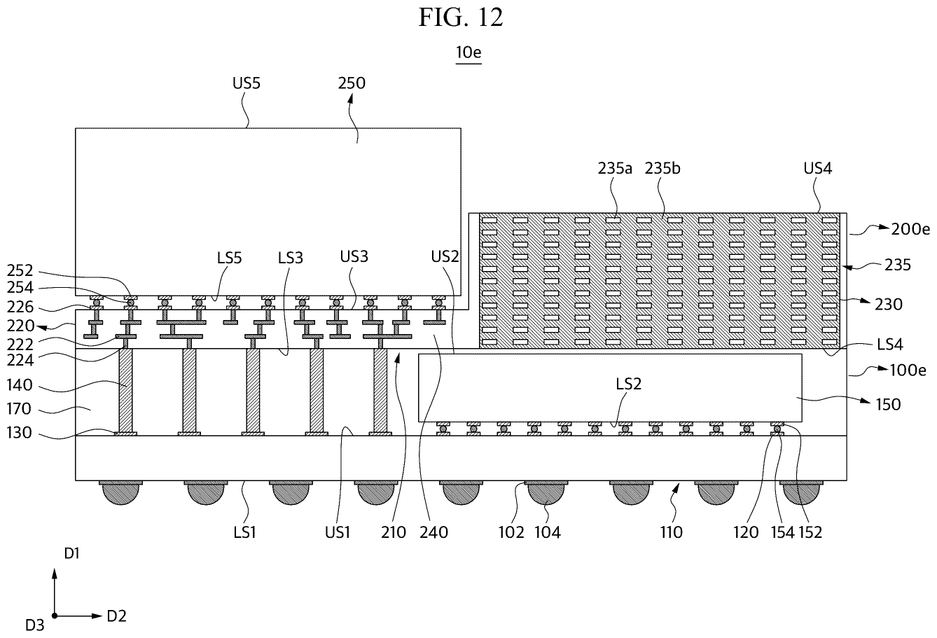

Referring to FIG. 12, in a semiconductor package 10e according to some example embodiments, an upper surface US4 of a heat radiation structure 230e may be positioned to be lower than the upper surface US5 of the upper semiconductor device 250. For example, the upper semiconductor device 250 may have a larger vertical distance from the upper surface US1 of the lower package substrate 110.

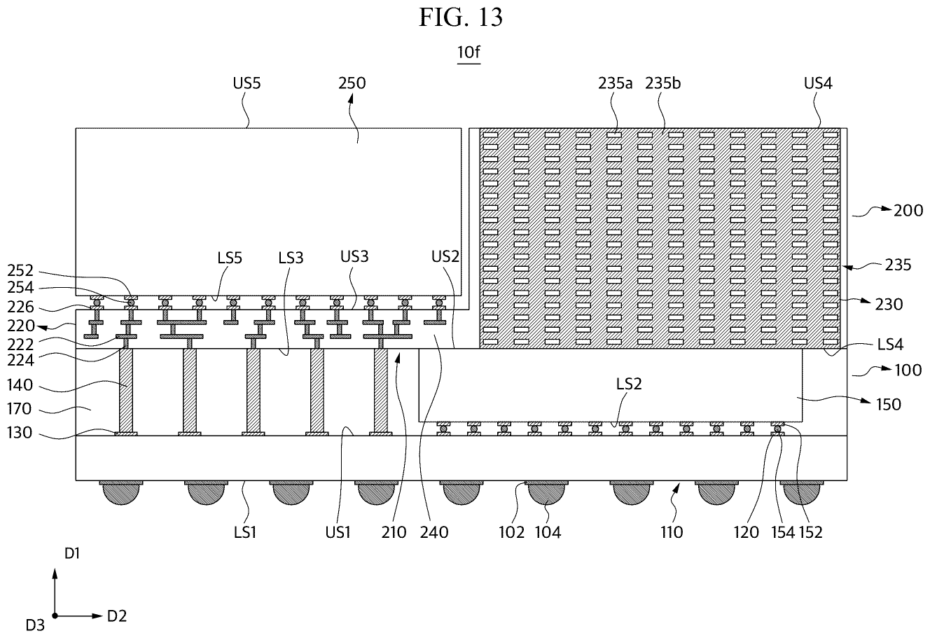

Referring to FIG. 13, in a semiconductor package 10f according to some example embodiments, the lower semiconductor device 150 may be disposed to be exposed from the mold film 170. For example, the upper surface US2 of the lower semiconductor device 150 and an upper surface of the mold film 170 may be coplanar. Accordingly, the lower semiconductor device 150 may be in areal contact with the upper package 200. For example, a portion of the upper surface US2 of the lower semiconductor device 150 may be in areal contact with at least a portion of the lower surface LS3 of the wiring structure 220, and another portion of the upper surface US2 of the lower semiconductor device 150 may be in areal contact with at least a portion of the lower surface LS4 of the heat radiation structure 230. For example, the lower semiconductor device 150 may contact the portion of the lower surface LS3 of the wiring structure 220 in the above-described first area A1 (see FIG. 1) and may contact the portion of the lower surface LS4 of the heat radiation structure 230 in the second area A2 (see FIG. 1). Accordingly, since heat generated in the lower semiconductor device 150 may be directly sent to the heat radiation structure 230, a heat radiation effect may be further improved. In addition, according to some other example embodiments, the upper surface US2 of the lower semiconductor device 150 may be exposed from the mold film 170, and the lower package 100 and the upper package 200 may be bonded by the above-described package connector 202 (see FIG. 7).

Some example embodiments described with reference to FIG. 13 may be applied, in an identical way, to example embodiments described with reference to FIGS. 1 through 12. For example, although an example in which the mold film 170 is placed between the lower semiconductor device 150 and the upper package 200 has been described in FIGS. 1 through 12, the lower semiconductor device 150 may be exposed from the mold film 170 to contact the lower surfaces LS3 and LS4 of the upper package 200 as described above.

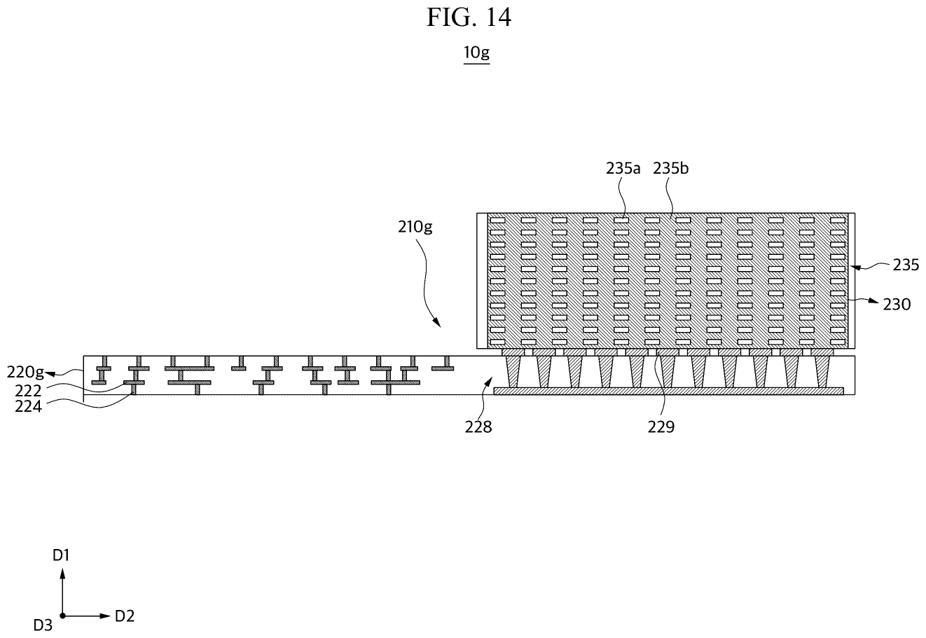

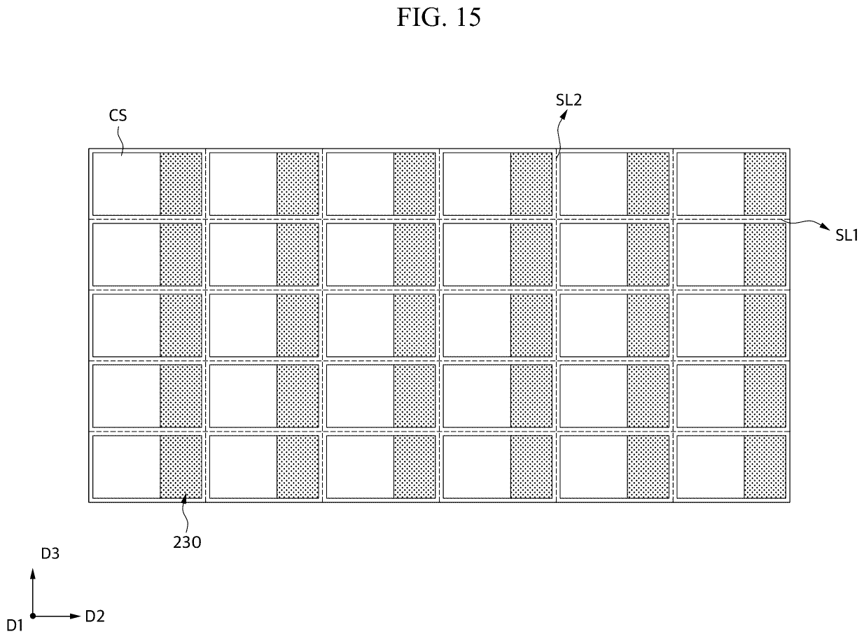

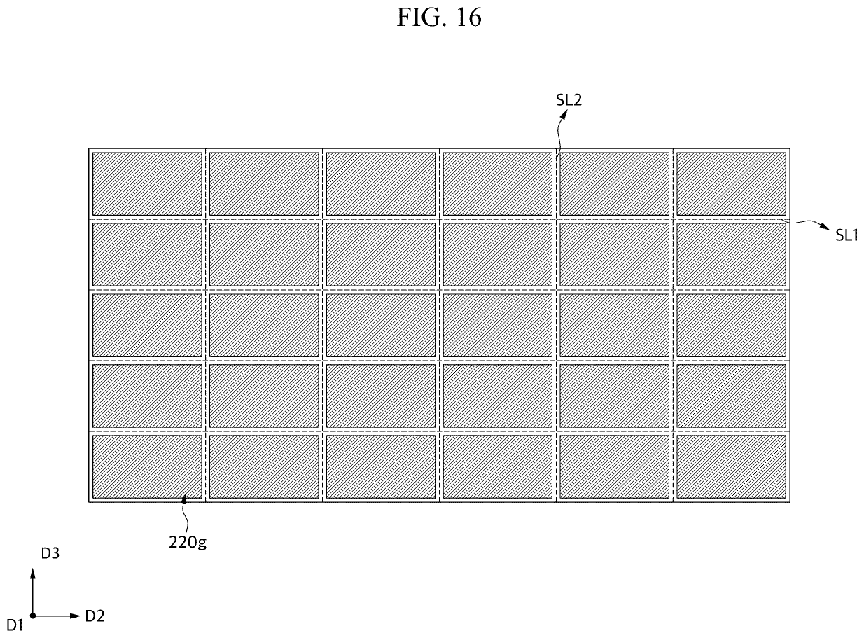

FIG. 14 is a cross-sectional diagram illustrating an outline of a shape of an upper package substrate according to still another example embodiment. FIG. 15 is a diagram illustrating an outline of a shape of a heat radiation structure of FIG. 14 being manufactured at a panel level. FIG. 16 is a diagram illustrating an outline of a shape of a wiring structure of FIG. 14 being manufactured at a panel level. An illustration of the above-described lower package is omitted in FIG. 14 in order to assist understanding. FIG. 16 illustrates an entire surface of a wiring structure 220g with oblique lines.

Referring to FIGS. 14 through 16, in a semiconductor package 10g according to some example embodiments, an upper package substrate 210g may include a wiring structure 220g and the heat radiation structure 230. According to some example embodiments, the wiring structure 220g and the heat radiation structure 230 may be disposed to overlap in the first direction D1. For example, the heat radiation structure 230 may be disposed on the wiring structure 220g to overlap at least a portion of the wiring structure 220g in the first direction D1. The wiring structure 220g according to some example embodiments may include the wiring lines 222 and 224 and a metal line 228. The wiring lines 222 and 224 and the metal line 228 may be disposed in different areas. In some example embodiments, an area in which the metal line 228 is disposed may overlap the heat radiation structure 230 in the first direction D1. In addition, although not illustrated, the area in which the metal line 228 is disposed may overlap, in the first direction D1, a lower semiconductor device mounted on a lower package substrate.

The metal line 228 may include a metal material. For example, the metal line 228 may include a metal material having excellent thermal conductivity. Also, the metal line 228 may include a metal material identical or similar to that of the wiring lines 222 and 224. In some example embodiments, as illustrated in FIG. 14, an upper portion of the metal line 228 may generally have a cross section having a tapered shape, and a lower portion of the metal line 228 may generally have a cross section having a rectangular shape. For example, the lower portion of the metal line 228 may have a cross-sectional area larger than that of the upper portion of the metal line 228. Due to such a shape of the metal line 228, heat generated in the lower semiconductor device which is disposed below the metal line 228 may be effectively sent to the heat radiation structure 230. However, this is merely an example. A shape of a cross section of the metal line 228 may be variously changed. Furthermore, FIG. 14 illustrates that a heat radiation pattern 235 of the wiring structure 220g has a structure stacked in multiple layers in the first direction D1, but this is merely an example. For example, the wiring structure 220g may have a heat radiation pattern 235 which is a single layer.

According to some example embodiments, as illustrated in FIGS. 15 and 16, the heat radiation structure 230 and the wiring structure 220g may be manufactured at a panel level. At this point, the heat radiation structure 230 may be formed on a panel-level carrier substrate CS. The carrier substrate CS may be removed after the heat radiation structure 230 and the wiring structure 220g are bonded. Each of pluralities of heat radiation structures 230 and wiring structures 220g manufactured at the panel level may be attached by solder 229 (see FIG. 14) through a reflow process. Each of the pluralities of heat radiation structures 230 and wiring structures 220g manufactured at the panel level may be cut along the first sawing line SL1 and the second sawing line SL2. However, this is merely an example. The heat radiation structures 230 and the wiring structures 220g may be individually attached by the solder 229 after being individually cut. According to some example embodiments described with reference to FIGS. 7 through 16, a structure of a semiconductor package may be flexibly changed depending on a type of an upper semiconductor device, a design requirement, and/or a heat radiation requirement.

Some example embodiments described above may be combined in various forms to be reconfigured as other modified example embodiments unless descriptions thereof are not contradictory to each other.

The above detailed descriptions are to show an example of the present disclosure. Also, the above contents are to show and describe a desired example embodiment of the present disclosure, and the present disclosure may be used in other various combinations, modifications, and environments. For example, a modification or a variation is allowed within a range of the concept of the present disclosure, a range equivalent to the disclosed descriptions therein, and/or a range of technology and knowledge of the related art. The disclosed example embodiments are to describe a possible state for implementing the technical spirit of the present disclosure. Various modifications that are required in a specific application field and usage of the present disclosure are also possible. Thus, the above detailed description does not intend to limit the present disclosure with the disclosed embodiments. Also, the accompanying claims should be construed as including another embodiment.

What is claimed is:

1. A semiconductor package comprising:
a lower package comprising a lower package substrate and a lower semiconductor device disposed on the lower package substrate; and
an upper package comprising an upper package substrate disposed on the lower package in a first direction and an upper semiconductor device disposed on the upper package substrate,
wherein the upper package substrate comprises:
a wiring structure on which the upper semiconductor device is mounted; and
a heat sink disposed so that at least a portion overlaps the wiring structure in at least one of the first direction and a second direction perpendicular to the first direction and including a heat radiation pattern,
wherein the heat radiation pattern comprises an insulator and a heat radiator arranged in a repeated alternating pattern in the first and second directions,
wherein the heat sink is exposed to an exterior of the semiconductor package, and
wherein the lower semiconductor device overlaps at least a portion of the wiring structure and the portion of the heat sink in the first direction.

2. The semiconductor package of claim 1, wherein the heat radiation pattern is formed by alternatingly disposing insulating material that forms the insulator and heat conductive material that forms the heat radiator, and
the heat radiator is disposed at at least one of an upper surface and a lower surface of the heat sink.

3. The semiconductor package of claim 2, wherein the heat sink is formed by stacking the heat radiation pattern in multiple layers in the first direction.

4. The semiconductor package of claim 2, wherein an upper surface of the lower semiconductor device is spaced apart from the lower surface of the heat sink.

5. The semiconductor package of claim 4, wherein a heat radiation pad is disposed between the lower semiconductor device and the heat sink, and
the heat radiation pad is in contact with each of the upper surface of the lower semiconductor device and the lower surface of the heat sink.

6. The semiconductor package of claim 2, wherein:
a side surface of the heat sink is surrounded by an insulation film,
the insulator and the insulation film are formed in an identical unit process, and
the insulator and a wiring line disposed in the wiring structure is formed in an identical unit process.

7. The semiconductor package of claim 1, wherein the wiring structure and the heat sink are integrally formed.

8. The semiconductor package of claim 1, wherein an upper surface of the lower semiconductor device and an upper surface of the heat sink are coplanar.

9. The semiconductor package of claim 1, wherein the lower package further comprises a conductive structure disposed on the lower package substrate and electrically connected to the lower package substrate and the wiring structure,
the lower semiconductor device further comprises:
a first area overlapping a portion of the upper semiconductor device in the first direction; and
a second area overlapping the portion of the heat sink in the first direction,
the conductive structure is disposed to be adjacent to the lower semiconductor device in the second direction, and
a size of the second area is larger than a size of the first area.

10. The semiconductor package of claim 1, wherein a lower surface of the wiring structure and a lower surface of the heat sink are coplanar.

11. The semiconductor package of claim 1, wherein each of the lower package and the upper package is formed at a panel level to be electrically connected to each other.

12. The semiconductor package of claim 1, wherein each of the wiring structure and the heat sink is formed at a panel level,
the heat sink and the wiring structure are attached by solder, and
the heat sink overlaps at least a second portion of the wiring structure in the first direction.

13. The semiconductor package of claim 1, wherein the heat sink comprises a first heat sink and a second heat sink symmetrically disposed around the upper semiconductor device with the upper semiconductor device in between,
each of the first heat sink and the second heat sink comprises the heat radiation pattern which is stacked in multiple layers,
the lower semiconductor device overlaps at least a portion of the first heat sink and at least a portion of the upper semiconductor device in the first direction, and
another lower semiconductor device overlaps at least a portion of the second heat sink and at least another portion of the upper semiconductor device in the first direction.

14. The semiconductor package of claim 1, wherein the upper semiconductor device is a first semiconductor device of two semiconductor devices formed on the upper package substrate, the two semiconductor devices comprising:
the first semiconductor device; and
a second semiconductor device,
the wiring structure comprises:
a first wiring structure on which the first semiconductor device is mounted; and
a second wiring structure on which the second semiconductor device is mounted,
the first wiring structure and the second wiring structure are formed at opposite sides of the heat sink, and
the lower semiconductor device overlaps at least a portion of the first wiring structure, at least a portion of the second wiring structure, and the at least a portion of the heat sink in the first direction in different areas.

15. The semiconductor package of claim 1, wherein at least a portion of an upper surface of the lower semiconductor device is in contact with at least a portion of a lower surface of the heat sink.

16. A semiconductor package comprising:
a package substrate; and
a semiconductor chip,
wherein the package substrate comprises:
a wiring structure in which a wiring line is formed and on which the semiconductor chip is mounted; and
a heat sink to which a heat radiation pattern configured to emit heat is formed, and
wherein the wiring structure and the heat sink are integrally formed.

17. The semiconductor package of claim 16, wherein an upper surface of the semiconductor chip and an upper surface of the heat sink are coplanar, and
a lower surface of the wiring structure and a lower surface of the heat sink are coplanar.

18. The semiconductor package of claim 16, wherein a lower surface of the wiring structure and a lower surface of the heat sink are coplanar, and
an upper surface of the heat sink is positioned higher than an upper surface of the wiring structure.

19. The semiconductor package of claim 16, wherein the heat radiation pattern is formed by alternatingly disposing insulating material that forms the insulator and heat conductive material that forms a heat radiator, and
the heat radiator is exposed at an upper surface and a lower surface of the heat sink.

20. A semiconductor package comprising:
a lower package substrate;
an upper package substrate disposed on the lower package substrate in a first direction and to which a wiring structure including a wiring line is formed and a heat sink having a multilayer structure to which a plurality of heat radiation patterns is formed are integrally formed;
a lower semiconductor device disposed on the lower package substrate and electrically connected to the lower package substrate;
an upper semiconductor device disposed on the wiring structure and electrically connected with the wiring structure;
a conductive structure disposed between the wiring structure and the lower package substrate and electrically connected to the wiring structure and the lower package substrate;
a mold film surrounding the wiring structure and the lower semiconductor device; and
an insulation film surrounding the wiring line and the heat radiation patterns,
wherein the lower semiconductor device is disposed to overlap a portion of the heat sink and a portion of the wiring structure in the first direction,
the mold film is spaced apart from an upper surface of the lower semiconductor device and the upper surface of the lower semiconductor device is in contact with the heat sink,
a heat radiation pad comprising a metal material in a space between the lower semiconductor device and heat sink, and
an upper end and a lower end of the heat radiation pad are in contact with the heat sink and the lower semiconductor device, respectively.
